(19) United States
(12) Patent Application Publication
(10) Pub. No.: US 2009/0266403 A1
(43) Pub. Date: Oct. 29, 2009

(54) SOLDER REPLACEMENT BY CONDUCTIVE TAPE MATERIAL

(75) Inventors: Shirish Shah, San Ramon, CA (US); Abhay Maheshwari, Monte Sereno, CA (US); Kevin R. Gibson, Redwood City, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Solaria Corporation, Fremont, CA (US)

(21) Appl. No.: 12/429,912

(22) Filed: Apr. 24, 2009

Related U.S. Application Data
(60) Provisional application No. 61/048,539, filed on Apr. 28, 2008.

(51) Int. Cl. H01L 31/052; H01L 31/042; H01L 21/50

(52) U.S. Cl. 136/246; 136/244; 438/64; 257/E21.499

(57) ABSTRACT

A method of forming a solar device. The method includes providing one or more photovoltaic cells having a front surface region and a back surface region. The method includes providing a first conductor element having a first side operably coupled to a first region of the front surface region of the one or more photovoltaic cells and a second side. In a specific embodiment, the conductor element includes a first anisotropic conducting tape material or a first conducting tape material, the first conducting element having a first thickness, a first length, and a first width. The method performs a bonding process to cause the first conductor element to conduct electric current in a first selected direction.

### CROSS-REFERENCES TO RELATED APPLICATIONS

This application claims priority to U.S. Provisional Application No. 61/048,539 filed Apr. 28, 2008, commonly assigned, and hereby incorporated by reference for all purpose. This application is related to U.S. application Ser. No. 11/445,933 filed Jun. 2, 2006, commonly assigned and hereby incorporated by reference for all purposes.

### BACKGROUND OF THE INVENTION

The present invention relates generally to solar energy techniques. In particular, the present invention provides a method and resulting structure for fabricating a photovoltaic device. In particular, embodiments according to the present invention provides a method and a resulting photovoltaic device free of a solder material. Merely by way of example, the invention has been applied to solar panels, but it would be recognized that the invention has a much broader range of applicability.

As the population of the world increases, industrial expansion has lead to an equally large consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable! Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

From the above, it is seen that techniques for improving solar devices is highly desirable. Particularly, for packaged design fabrication of the photovoltaic cell, panel, or assembly coupled with light concentration module, there are needs for an interface pattern with desired physical, electrical, and optical coupling properties.

### BRIEF SUMMARY OF THE INVENTION

Embodiments according to the present invention relate to solar energy techniques. In particular, embodiments according to the present invention provide a method and resulting structure for fabricating a photovoltaic device. In particular, embodiments according to the present invention provides a method and a resulting photovoltaic device free of a solder material. Merely by way of example, the invention has been applied to solar panels, but it would be recognized that the invention has a much broader range of applicability.

In a specific embodiment, a method of forming a solar device is provided. The method includes providing one or more photovoltaic cells, the one or more photovoltaic cells comprising a front surface region and a back surface region. The method provides a first conductor element having a first side operably coupled to a first region of the front surface region of the one or more photovoltaic cells. The conductor element includes a first anisotropic conducting tape material in a specific embodiment. In an alternative embodiment, the conductor element uses a first conducting tape material. The first conducting element includes a first thickness, a first length, and a first width. The method includes performing a bonding process to cause the first conductor element to conduct electric current in a first selected direction and the second conductor element to conduct electric current in a second selected direction.

In an alternative embodiment, a solar cell device is provided. The solar cell device includes one or more photovoltaic cells. The one or more photovoltaic cells include a front surface region and a backside surface region. The solar cell device includes a first conductor element. The first conductor element includes a first side operably coupled to a first region of the front surface region of the one or more photovoltaic cells and a second side. In a specific embodiment, the first conductor element is provided using a first anisotropic conducting tape material, the first conducting element having a first thickness, a first length, and a first width.

Many benefits can be achieved by way of the embodiments of the present invention over conventional techniques. For example, the present technique provides an easy to use process that relies on conventional technology and materials. Additionally, the method provides a process that is compatible with conventional process technology without substantial modifications to conventional equipment and processes. Preferably, the invention provides for an simplified process and a solar device free of a rigid solder material. The absence of the rigid solder material allows for expansion or contraction of a photovoltaic cell due to temperature fluctuation of the ambient. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagrams illustrating a convention photovoltaic device.

FIG. 2-7 are simplified diagrams illustrating a method of forming a solar cell device according to an embodiment of the present invention.

FIG. 8 is a simplified diagram illustrating a solar cell device according to an embodiment of the present invention.

### DETAILED DESCRIPTION OF THE INVENTION

Embodiments according to the present invention relate to solar energy techniques. In particular, embodiments according to the present invention provide a method and resulting structure for fabricating a photovoltaic device. More particularly, embodiments according to the present invention provides a method and a resulting photovoltaic device free of a solder material. Merely by way of example, the invention has been applied to solar panels, but it would be recognized that the invention has a much broader range of applicability.

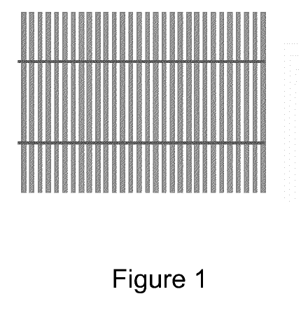

FIG. 1 illustrates a conventional way of manufacturing a photovoltaic device. A plurality of photovoltaic cells 102 are provided. For examples, the photovoltaic cells are provided as photovoltaic strips. These strips are then electrically connected in a back side and a front side of the plurality of photovoltaic cells. Electrical connections conventionally are done using a copper (Cu) strip or Cu alloy with a protective nickel or gold plating. Free movements of photovoltaic cells are restricted due to the stiffness of the Cu strips 104 (or bus bar) as illustrated in FIG. 1. A certain degree of free movement is desirable to provide for a difference in thermal expansion between the photovoltaic material and the electrical connecting material. These and other limitation would be described throughout the specification and particularly below.

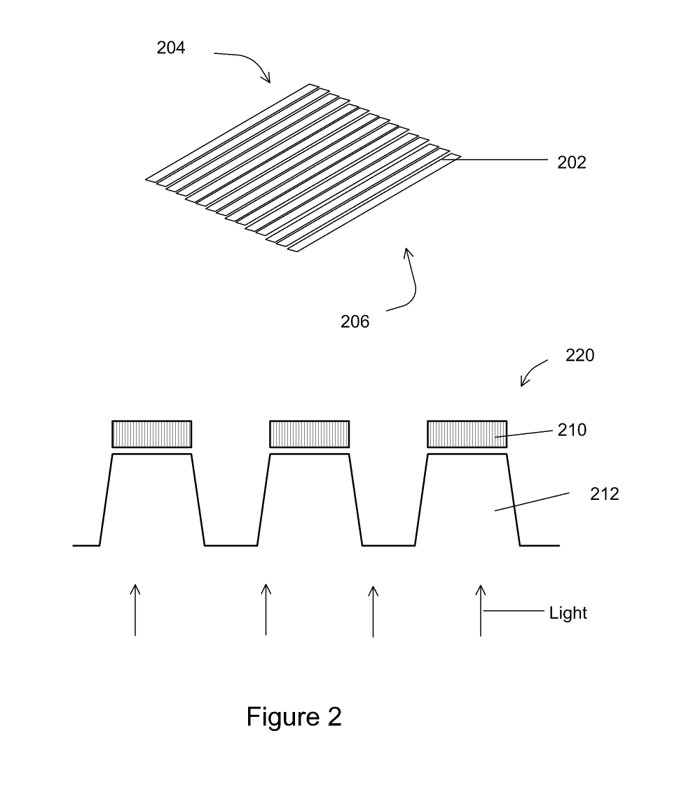

FIGS. 2-7 are simplified method illustrating a method of forming a solar device according to an embodiment of the present invention. As shown, one or more photovoltaic cells 202 are provided. The one or more photovoltaic cells can be provided as one or more photovoltaic strips in a specific embodiment. The one or more photovoltaic cells can also be provided in a single piece of photovoltaic material in an alternative embodiment. As shown, the one or more photovoltaic cells include a front surface region 204 and a back surface region 206. In certain embodiment, the one or more photovoltaic cells can be provided using material selected from thin film such as CIGS, cadmium telluride, amorphous silicon, or other semiconductor materials. In other embodiments, the one or more photovoltaic cells can be provided using a silicon based single crystal or polycrystalline solar cell material. In a specific embodiment, the one or more photovoltaic cells include a plurality of concentrator elements 212 operably coupled to respective photovoltaic regions 210 as shown in a cross sectional view 220 in FIG. 2. Of course there can be other modification, variations, and alternatives.

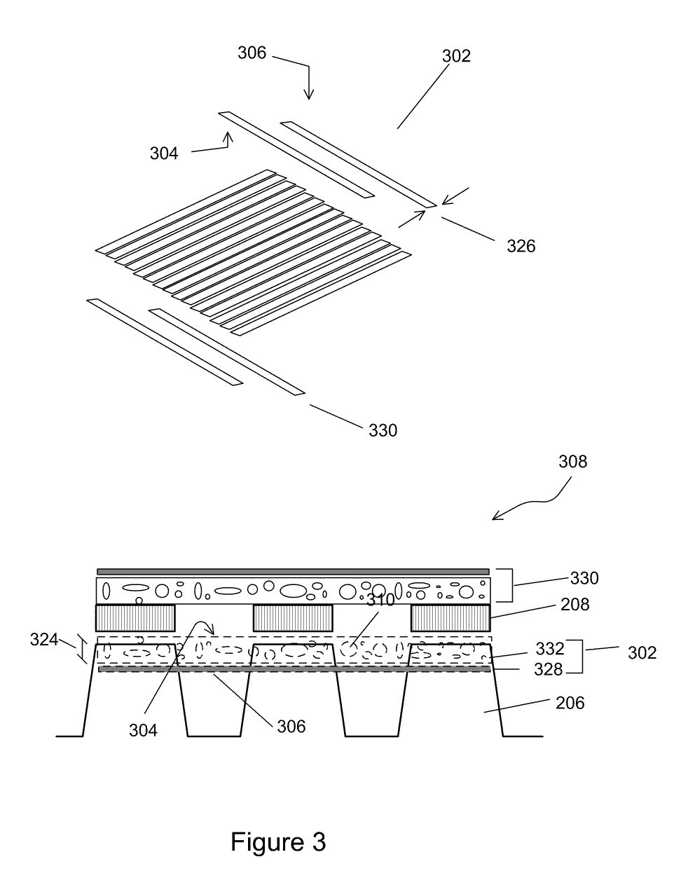

In a specific embodiment, the method includes providing one or more first conductor member 302 as shown in FIG. 3. Each of the one or more first conductor member include a first side 304 and a second side 306. As shown, the first side of the one or more conduct conductor member or member is operably couple to a first portion of the front surface region of the one or more photovoltaic cells. A simplified side view diagram 308 is also shown. In a specific embodiment, the first conductor member uses a first anisotropic conducting tape material 332. As sown, the first anisotropic conducting tape material includes a thickness 324. In a specific embodiment, the first anisotropic tape material can have a width 326 ranging from about 0.5 mm to about 15 mm. In a specific embodiment a metal material 328 is provided overlying the second side of the one or more conductor member. As shown, the anisotropic conducting tape material includes a plurality of anisotropic conducting particles 310. Of course there can be other variations, modifications, and alternatives.

As shown in FIG. 3A, each of the plurality of the anisotropic conducting particles includes a substantially spherical polymer particle 314. Each of the plurality of the anisotropic conducting particles also includes one or more metal layers 316 cladded between the substantially spherical polymer particle and an insulating 318. The one or more metal layers can include material such as a gold layer overlying a nickel layer in a specific embodiment.

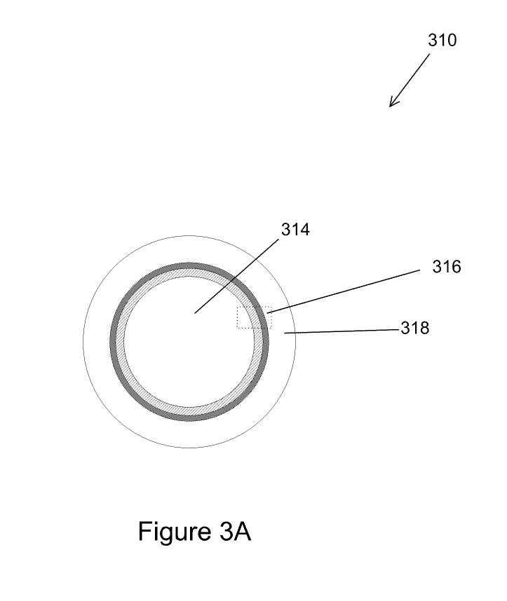

Referring again to FIG. 3, in certain embodiment, the method provides one or more second conductor elements 330 using the first anisotropic tape material couple to a portion of the back surface region of the one or more photovoltaic cells. Though an isotropic tape material is illustrated, other variations can be provided. For example, in certain embodiments, the one or more second conductor elements can use a second anisotropic tape material. Yet in certain other embodiment, other conductor material such as a metal material 402 may be used for the second conductor element as shown in FIG. 4. Of course there can be other variations, modifications, and alternatives.

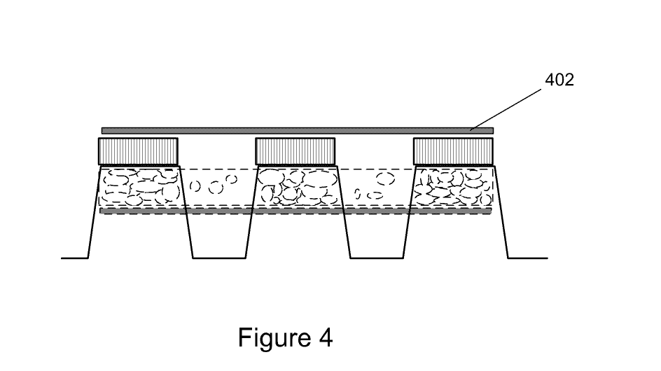

In a specific embodiment, a bonding process 502 is performed on the first conductor element and the second conductor element including the concentrator element in a specific embodiment. as shown in the simplified diagram of FIG. 5. The bonding process includes a pressure process 504 followed by a thermal process 506 in a specific embodiment. In a specific embodiment, the pressure process can be provided using a pressure ranging from about 0.8 kg per cm² to about 5 kg per cm² but can also be others depending on the embodiment. The thermal process is provided at a temperature ranging from about 50 Degree Celsius to about 150 Degree Celsius in a specific embodiment. In certain embodiments, the bonding process is providing for a time period ranging from about 0.5 second to about 50 seconds. Of course one skilled in the art would recognize other variations, modifications, and alternatives.

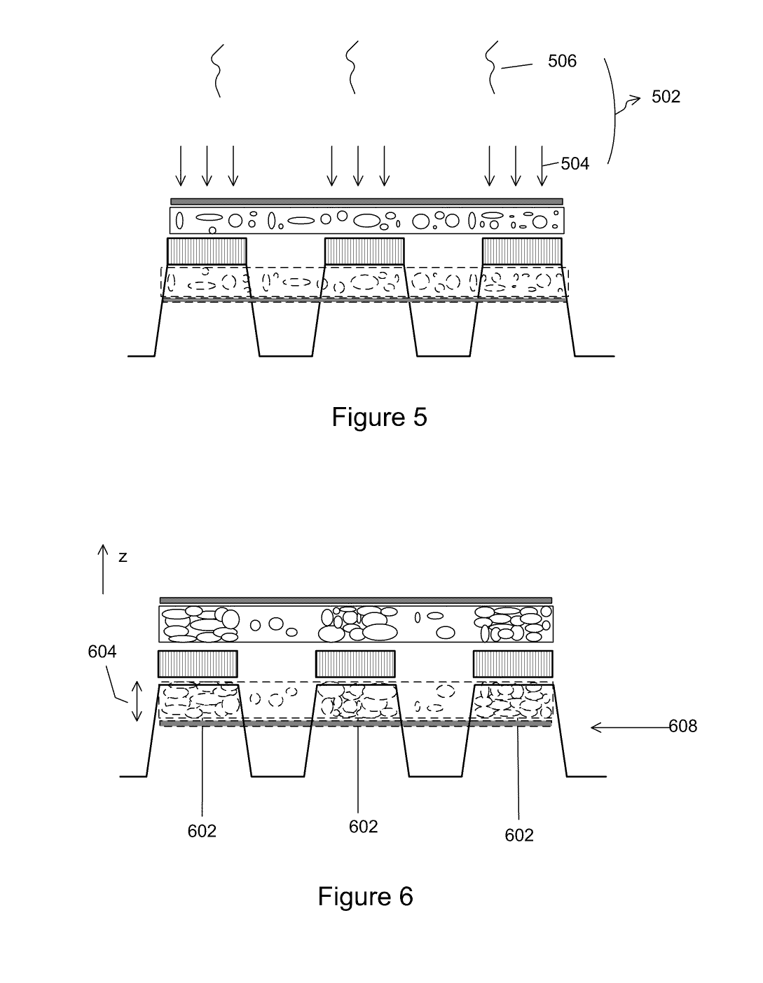

As shown in FIG. 6, the bonding process causes shrinkage of the respective anisotropic conductive tape material allowing the plurality of conducting particles to be trapped in respective conducting region 602 in the first anisotropic conducting tape material to cause the first conductor element to conduct electric current in a selected direction 604. The selected direction is a z-direction along the thickness of the first conductor element in a preferred embodiment. As shown, the metal material overlying the respective anisotropic conductor tape material electrically connects the plurality of photovoltaic strips and allow electric current to flow in a direction 608 along respective lengths of the respective anisotropic conductive tape material. Depending on the application, the metal strip can be of a suitable thickness allowing a desirable electric current to flow. Of course there can be other modification, variations, and alternatives.

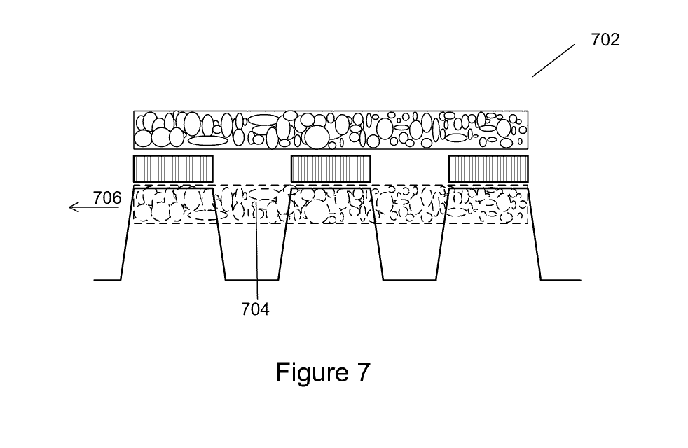

Alternatively, the first conductor element can be provided using a first conductive tape material 702 operably coupled to the one or more photovoltaic strips as shown in FIG. 7. The conductive tape material includes a plurality of conducting particles 704 as shown. In a specific embodiment, the conductive tape material can include a pressure sensitive material. Upon a bonding process, the plurality of conducting particles are distributed within the entire length of conductive tape material (xyz or 3D loading) to allow electrical connection of the plurality of the one or more photovoltaic cells. The bonding process can include a pressure and thermal process in a specific embodiment. In certain embodiment, the second conductor element may be provide using a second conductive tape material coupled to the front surface region of the one or more photovoltaic strips. In other embodiment, the second conductor element may be provide using other suitable conducting materials. Of course one skilled in the art would recognize other variations, modifications, and alternatives.

In a specific embodiment, the respective conducting tape materials provide mechanical characteristics that are flexible to accommodate differences in thermal expansion between the respective conductor elements and the one or more photovoltaic cells. Additionally, the respective conducting tape materials allow for stress reduction and eliminates deformation of the one or more photovoltaic cells thereby improve an overall device reliability in a preferred embodiment. Of course there can be other variations, modifications, and alternatives.

Depending on the embodiment, there can be variations. For example, an adhesive layer may be provided to facilitate placement of the respective conducting tape materials on the surface region of the one or more photovoltaic cells or a suitable carrier member. The adhesive layer is preferably having suitable properties that would not affect electrical conduction from the respective photovoltaic region and the respective conducting tape materials. In certain embodiment, the adhesive layer is also characterized by a suitable optical property. In an alternative embodiment, the respective conductor element may be provided using a pressure sensitive material. Of course there can be other variations, modifications, and alternatives.

In a specific embodiment, the method further provides a transparent substrate member and a back cover member to allow an isolated environment for the one or more photovoltaic cells including the respective conductor elements and other electrical interconnects. Of course there can be other variations, modifications, and alternatives.

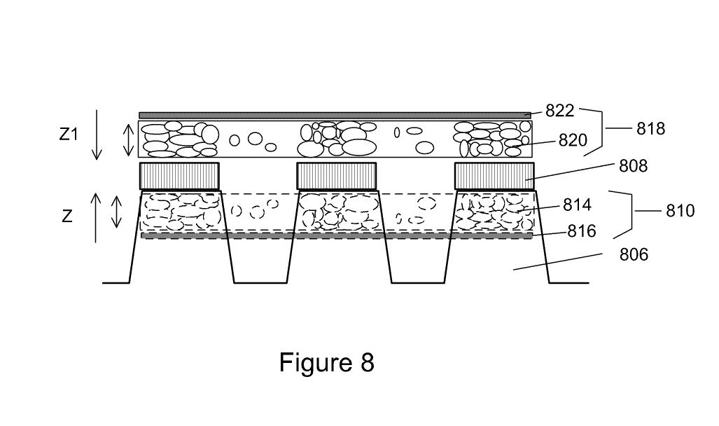

FIG. 8 is a simplified diagram illustrating a solar cell device 800 according to an embodiment of the present invention. This diagram is merely an example and should not unduly limit the claims herein. One skilled in the art would recognize other modifications, variations, and alternatives. As shown, one or more photovoltaic cells 802 are provided. The one or more photovoltaic cells includes a front surface region 804. The one or more photovoltaic cells are provided as a plurality of photovoltaic strips in a specific embodiment. In a preferred embodiment, the solar cell device includes a plurality of concentrator elements 806 coupled to respective of photovoltaic regions 808 in a specific embodiment. In other embodiments, the one or more photovoltaic cells can be provided in a single piece of a photovoltaic material. In certain embodiment, the one or more photovoltaic cells can be provided using material selected from thin film such as CIGS, cadmium telluride, amorphous silicon, or other semiconductor materials. In other embodiments, the one or more photovoltaic cells can be provided using a silicon based single crystal or polycrystalline solar cell material. Of course there can be other modification, variations, and alternatives.

In a specific embodiment, the solar device include one or more first conductor element 810 operably coupled to a first portion of a front surface of the one or more photovoltaic cells. In a specific embodiment the one or more first conductor element uses a first anisotropic conducting tape material 814 having a first anisotropic conducting characteristic. That is the first anisotropic conducting tape material conducts electrical current in a selected direction in a specific embodiment. As shown, the first anisotropic conducting tape material conducts electrical current in a direction along a thickness (or z direction) of the first anisotropic conducting tape material. As shown, a conductive material 816 is provided to electrically connect the one or more conductive regions in the first anisotropic conducting tape material in a preferred embodiment.

Referring to FIG. 8, the solar device includes one or more second conductor element 818 operably coupled to a second portion of a back surface of the one or more photovoltaic cells In a specific embodiment the one or more second conductor elements use a second anisotropic conducting tape material 820 having a second anisotropic conducting characteristic and a second conductive material 822. The second anisotropic conducting tape material conducts electrical current in a selected direction in a specific embodiment. As shown, the second anisotropic conducting tape material conducts electrical current in a direction along the thickness (or zl direction) of the second conductor element uses a second anisotropic conducting tape material having a second anisotropic conducting characteristic. In certain embodiments, the second conductor element and the first conductor element may also use the same anisotropic conducting tape material. In an alternative embodiment, the second conductor material may use a metal material (for example, aluminum, gold, silver, copper, and the like). Of course one skilled in the art would recognize other variations, modifications, and alternatives.

Depending upon the embodiment, there can be other variations. For example, the first conductor member may use a conductive tape material and the second conductor member may use a metal material. Or, the first conductor member may use a first conductive tape material and the second conductor member may use a second conductive tape material depending on the application. Of course one skilled in the art would recognize other variations, modifications, and alternatives.

In a specific embodiment, the solar cell device is packaged using a transparent substrate member and a back cover member to seal and isolate the solar cell from the environment. In a specific embodiment, an encapsulating material may be provided to protect the solar device from elements such as moisture and others. Of course there can be other variations, modification, and alternatives.

It is also understood that the examples and embodiments described herein are for illustrative purposes only and that various modifications or alternatives in light thereof will be suggested to persons skilled in the art and are to be included within the spirit and purview of this application and scope of the appended claims.

What is claimed is:

1. A method of forming a solar device, comprising:
providing one or more photovoltaic cells, the one or more photovoltaic cells comprising a front surface region and a back surface region;
providing a first conductor element having a first side operably coupled to a first region of the front surface region of the one or more photovoltaic cells and a second side, the conductor element comprising a first anisotropic conducting tape material or a first conducting tape material, the first conducting element having a first thickness, a first length, and a first width; and
performing a bonding process to cause the first conductor element to conduct electric current in a selected direction.

2. The method of claim 1 further comprises providing a second conductor element comprising a third side operably coupled to a second region of the backside surface region of the one or more photovoltaic cells and a fourth side, the second conductor element being provided using a second anisotropic conducting material or a second conducting tape material, the second conducting element having a second thickness, a second length, and a second width

3. The method of claim 1 wherein the solar device is free of a solder material.

4. The method of claim 1 wherein the one or more photovoltaic cells comprises a material selected from CIGS, cadmium telluride, amorphous silicon, or other semiconductor materials.

5. The method of claim 1 wherein the one or more photovoltaic cells comprises a silicon based single crystal or polycrystalline solar cell.

6. The method of claim 1 wherein the respective anisotropic conducting material comprises an anisotropic conducting characteristics provided by trapping a plurality of anisotropic conductive particles within the respective conductor element and the respective surface region of the one or more photovoltaic cells.

7. The method of claim 1 wherein the first conductor element and the second conductor element each has a width ranging from about 0.5 mm to about 15 mm.

8. The method of claim 6 wherein each of the plurality of conductive particles comprises one or more metal layers cladded between a substantially spherically polymer particle and an insulating layer.

9. The method of claim 6 wherein the respective anisotropic conductive material provides electrical conduction along a direction of the respective thickness of the respective anisotropic conductive material after the bonding process.

10. The method of claim 8 wherein the one or more metal layers comprise nickel and gold.

11. The method of claim 9 further comprises a third conductor layer coupled to the second side of the of the first conductor element and a fourth conductor layer coupled to the fourth side of the of the second conductor element.

12. The method of claim 11 wherein the third conductor layer and the fourth conductor layer comprises a metal material, the metal material being selected from: copper, gold, silver, or aluminum.

13. The method of claim 1 wherein the one or more photovoltaic cells further comprises a plurality of concentration elements coupled to respective plurality of photovoltaic regions.

14. The method of claim 1 wherein the one or more photovoltaic cells are sealed between a transparent substrate member and a back cover member.

15. The method of claim 1 wherein the bonding process comprising a pressure process and/or a thermal process, the bonding process causing the one or more metal layers of each of the anisotropic conducting particles to be exposed in selected areas allowing electrical conduction along the direction of the thickness of the first conductor element and the direction of the thickness of the second conductor element.

16. The method of claim 15 wherein the pressure process s provided at a pressure ranging from about 0.8 kg per cm² to about 5 kg per cm².

17. The method of claim 15 wherein the thermal process is provided at a temperature ranging from about 50 Degree Celsius to about 150 Degree Celsius.

18. The method of claim 15 wherein the bonding process is provided for between 0.5 and 50 seconds.

19. The method of claim 1 wherein the anisotropic conducting particles are provided in a pressure sensitive adhesive material.

20. A solar cell device, comprising:
one or more photovoltaic cells, the one or more photovoltaic cells comprising a front surface region and a backside surface region, and
a first conductor element comprising a first side operably coupled to a first region of the front surface region of the one or more photovoltaic cells and a second side, the first conductor element being provided using a first anisotropic conducting tape material, the first conducting element having a first thickness, a first length, and a first width.

21. The solar device of claim 20 further comprises a second conductor element comprising a third side operably coupled to a second region of the backside surface region of the one or more photovoltaic cells and a fourth side, the second conductor element being provided using the anisotropic conducting tape material, the second conducting element having a second thickness, a second length, and a second width.

22. The solar device of claim 20 wherein the anisotropic conducting tape material comprises an anisotropic conducting characteristics provided by trapping a plurality of conductive particles between the respective conductor element and the respective surface region of the one or more photovoltaic cells.

23. The solar device of claim 20 wherein the first conductor element and the second conductor element each has a width ranging from about 0.5 mm to about 15 mm.

24. The solar device of claim 22 wherein each of the plurality of conductive particles comprises one or more metal layers cladded between a substantially spherically polymer particle and an insulating layer.

25. The solar device of claim 24 wherein the one or more metal layers comprise nickel and gold.

26. The solar device of claim 22 wherein the respective conductive elements provide electrical conduction along a direction of the respective thickness of the respective conductive element.

27. The solar device of claim 22 further comprises a third conductor layer coupled to the second side of the of the first conductor element and a fourth conductor layer coupled to the fourth side of the of the second conductor element, the third conductor layer and the fourth conductor layer comprises a metal material, the metal material being selected from: gold, silver, copper, or aluminum.

28. The solar device of claim 20 wherein the one or more photovoltaic cells further comprises a plurality of concentration elements coupled to respective plurality of photovoltaic regions.

29. The solar device of claim 20 wherein the one or more photovoltaic cells, including the respective conductor elements and electrical interconnects are sealed between a transparent substrate member and a back cover member.
